(19) United States
(12) Patent Application Publication
(10) Pub. No.: US 2010/0006032 A1
(43) Pub. Date: Jan. 14, 2010

(54) CHAMBER COMPONENTS FOR CVD APPLICATIONS

(75) Inventors: Kimberly Hinckley, Mountain View, CA (US); Yizhen Zhang, Sunnyvale, CA (US); Manuel A. Hernandez, Santa Clara, CA (US); Won B. Bang, Gilroy, CA (US); Dmitry Lubomirsky, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/501,195

(22) Filed: Jul. 10, 2009

Related U.S. Application Data
(60) Provisional application No. 61/080,206, filed on Jul. 11, 2008.
(60) Provisional application No. 61/092,369, filed on Aug. 27, 2008.
(60) Provisional application No. 61/092,695, filed on Aug. 28, 2008.

(51) Int. Cl. C23C 16/00

(52) U.S. Cl. 118/726; 118/715; 118/728

(57) ABSTRACT

Apparatus for use with a processing chamber are provided. In one aspect a blocker plate is provided including an annular plate having an inner portion of a first thickness and the annular plate having an aperture pattern including a center portion, a first patterned portion concentrically disposed around the center portion and comprising a first plurality of apertures having a first number of apertures, an second patterned portion concentrically disposed around the first patterned portion and comprising a second plurality of apertures having a second number of apertures greater than the first number of apertures, a perimeter portion concentrically disposed around the second patterned portion, and an outer portion comprising a raised concentric portion disposed on a perimeter of the annular plate. In another aspect, a second, third, and fourth blocker plates are provided. Additionally, a mixing apparatus and a liquid evaporating apparatus for use in a processing chamber are provided.

### CROSS-REFERENCE TO RELATED APPLICATIONS

This application claims benefit of U.S. Provisional Patent Application Ser. No. 61/080,206, filed Jul. 11, 2008, this application claims benefit of U.S. Provisional Patent Application Ser. No. 61/092,369, filed Aug. 27, 2008, and this application claims benefit of U.S. Provisional Patent Application Ser. No. 61/092,695, filed Aug. 28, 2008, which are all incorporated herein by reference in their respective entirety.

### BACKGROUND OF THE INVENTION

### Field of the Invention

Embodiments of the present invention generally relate to chamber components for chemical vapor deposition (CVD) applications.

In the manufacture of integrated circuits, precise control of various process parameters is necessary for achieving consistent results within a substrate, as well as the results that are reproducible from substrate to substrate. During processing, changes in processing gas flows and distributions across the substrate surface may be detrimental to material deposition rates, thickness, step coverage, uniformity of deposition, and other deposition parameters.

In some processing chambers, processing gases may be vaporized, delivered into a processing region of a chamber by a gas distributor, and reacted to deposit a desired material. The gas distributor may include a gas inlet passage which delivers the processing gases into a shower head assembly having a blocker plate disposed intermediate a face plate. The processing gas may be mixed prior to introduction to the processing region of the chamber. Conventional gas delivery systems may have insufficient means for vaporizing, mixing, and/or delivering processing gases to a processing region of a chamber. The inability to control processing gas delivery may have an adverse effect on process uniformity both within a single substrate and between substrates, device yield and overall quality of processed substrates.

Therefore, there is a need in the art for improved chamber components in a chemical vapor deposition chamber.

### SUMMARY OF THE INVENTION

Embodiments of the present invention generally relate to chamber components for chemical vapor deposition (CVD) applications. Embodiments of the present invention generally relate to blocker plate, a mixing apparatus, and a liquid evaporating apparatus for chemical vapor deposition chambers.

In one embodiment, a blocker plate is provided including an annular plate having an inner portion of a first thickness and the annular plate having an aperture pattern including a center portion, a first patterned portion concentrically disposed around the center portion and comprising a first plurality of apertures having a first number of apertures, an second patterned portion concentrically disposed around the first patterned portion and comprising a second plurality of apertures having a second number of apertures greater than the first number of apertures, a perimeter portion concentrically disposed around the second patterned portion, and an outer portion comprising a raised concentric portion disposed on a perimeter of the annular plate and having a second thickness greater than the first thickness of the center portion.

In another embodiment, a blocker plate is provided including an annular plate having an inner portion of a first thickness and the annular plate having an aperture pattern comprising a center portion comprising a plurality of apertures, wherein the plurality of apertures comprises a plurality of concentric circular rows each having an increasing number of apertures between 30 and 150 apertures with each ring having an angle of offset between 60° and 270° for a center line of the center portion, a perimeter portion concentrically disposed around the center portion, and an outer portion comprising a raised concentric portion disposed on a perimeter of the annular plate and having a second thickness greater than the first thickness of the inner portion.

In another embodiment, a blocker plate is provided including an annular plate having an inner portion of a first thickness and the annular plate having an aperture pattern comprising a center portion, a patterned portion concentrically disposed around the center portion and comprising a plurality of apertures, wherein the plurality of apertures comprises a plurality of concentric circular rows each having a varying number of apertures between 16 and 96 apertures with each ring having an angle of offset between 7° and 245° for a center line of the center portion, a perimeter portion concentrically disposed around the center portion, and an outer portion comprising a raised concentric portion disposed on a perimeter of the annular plate and having a second thickness greater than the first thickness of the inner portion.

In another embodiment, a mixing apparatus is provided including a cylindrical first portion extending from an inlet, a second portion coupled to the first portion, and a third portion coupled to the second portion and extending to an outlet, wherein the first portion has a conical shape and tapers from the inlet to the second portion and the third portion expands from the second portion to outlet.

In another embodiment, a mixing apparatus is provided including a first portion extending from an inlet, a cylindrical second portion coupled to the first portion, and a third portion coupled to the second portion and extending to an outlet with the third portion comprising an expanding portion coupled to the second portion and a cylindrical portion coupled to the expanding portion and the outlet and the first portion has a conical shape and tapers from the inlet to the second portion.

In another embodiment, a liquid evaporating apparatus is provided including a vaporizer, a mixed fluid line coupled to the vaporizer, a first fluid shutoff valve disposed on a top portion of the vaporizer and coupled to the mixed fluid line, a first fluid line coupled to the mixed fluid line by the first fluid shutoff valve, a second fluid line coupled to the mixed fluid line, and a vaporizer shutoff valve disposed in fluid communication with the vaporizer.

In another embodiment, a blocker plate is provided including an annular plate having a plurality of apertures.

In another embodiment, a mixer apparatus is provided including a cylindrical first portion extending from an inlet, a second portion coupled to the first portion, and a third portion coupled to the second portion and extending to an outlet, wherein the first portion has a conical shape and tapers from the inlet to the second portion and the third portion expands from the second portion to outlet.

In another embodiment, a liquid evaporator apparatus is provided including a vaporizer, a vaporizer shutoff valve disposed in fluid communication with the vaporizer, a mixed fluid line coupled to the vaporizer, a first fluid line coupled to a first fluid shutoff disposed on a top portion of the vaporizer, wherein the mixed fluid line is coupled to the first fluid shutoff valve, and a second fluid line coupled to the mixed fluid line.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of a deposition chamber according to embodiments described herein;

FIG. 2A is a schematic view of one embodiment of a blocker plate described herein;

FIG. 2B is a sectional view taken along line 2B of the blocker plate of FIG. 2A according to one embodiment described herein;

FIG. 2C is a schematic view of another embodiment of a blocker plate described herein;

FIG. 2D is a schematic view of another embodiment of a blocker plate described herein;

FIG. 3A is a schematic view of another embodiment of a blocker plate described herein;

FIG. 3B is a sectional view taken along line 3B of the blocker plate of FIG. 3A according to one embodiment described herein;

FIG. 4A is a cross-sectional view of the funnel mixing tube according to embodiments described herein;

FIG. 4B is a cross-sectional view of one embodiment of a funnel mixing tube disposed in a gas distribution assembly;

FIG. 4C is a perspective view of one embodiment of the funnel mixing tube of FIG. 4A;

FIGS. 5A and 5B are schematic top and side views of a liquid evaporator according to one embodiment described herein;

FIG. 5C is a perspective view of one embodiment of a vaporizer disposed in the liquid evaporator;

FIG. 5D is a schematic side view of one embodiment of the vaporizer; and

FIG. 6 is a schematic diagram for the electronic system of the liquid evaporator according to one embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention provide apparatus for chemical vapor deposition (CVD) processing chambers. The deposition chambers that may benefit from the apparatus and methods described herein include chambers that may be used to deposit oxides, such as carbon-doped silicon oxides, silicon containing films, and other dielectric materials including advanced patterned films (APF). An example of a deposition chamber is the series of Producer® Chambers, available from Applied Materials, Inc. of Santa Clara, Calif. The Producer® Chamber is a CVD chamber with two isolated processing regions that may be used to deposit carbon-doped silicon oxides and other materials. A chamber having two isolated processing regions is described in U.S. Pat. No. 5,855,681, which is incorporated by reference. The Producer® Chamber has a port to which remote plasma sources may be attached.

In the embodiments described herein, a remote plasma source may be attached to a Producer® chamber such that one remote plasma source is connected to both isolated processing regions of the Producer® chamber. However, the processes described below may also be performed by using two remote plasma sources connected, for example, by a tee line, to each processing region of the Producer® Chamber and by adjusting the flow rates accordingly.

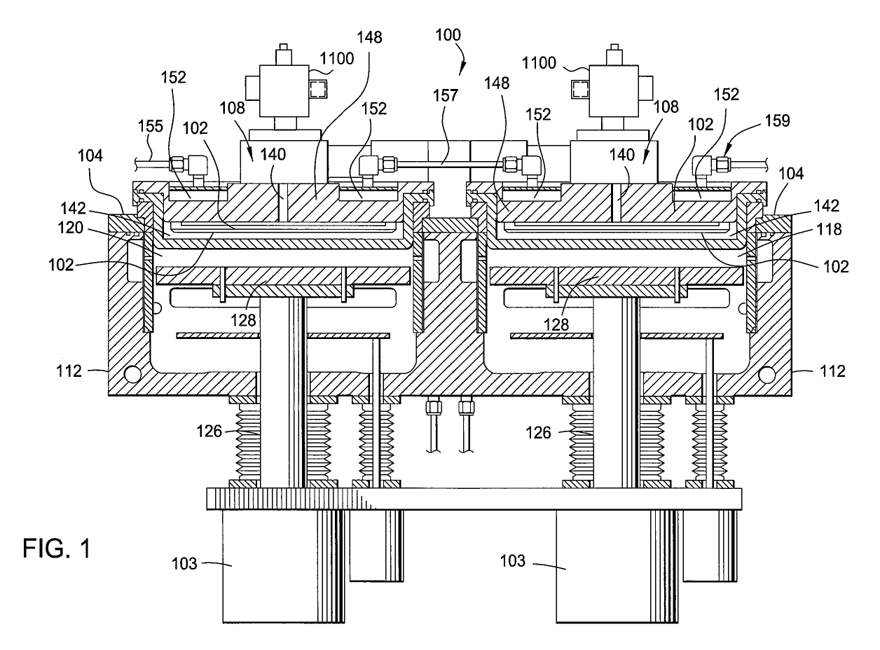

FIG. 1 is a schematic view of a chamber 100 that has two processing regions, 118, 120 connected to two remote plasma sources 1100. One remote plasma source 1100 is connected to processing region 118, and the other remote plasma source 1100 is connected to processing region 120. A heater pedestal 128 is movably disposed in each processing region 118, 120 by a stem 126 which extends through the bottom of the chamber body 112 where it is connected to a drive system 103. Each of the processing regions 118, 120 includes a gas distribution assembly comprising a gas box 142 disposed through the chamber lid 104 to deliver gases into the processing regions 118, 120 through blocker plates 102. The gas distribution assembly 108 of each processing region also includes a gas inlet passage 140 which delivers gas into a gas box 142. A cooling channel 152 is formed in a base plate 148 of each gas distribution assembly 108 to cool the plate during operation. An inlet 155 delivers a coolant fluid, such as water, into the cooling channels 152 which are connected to each other by coolant line 157. The cooling fluid exits the channel through a coolant outlet 159. Alternatively, the cooling fluid is circulated through the manifold. Processing gas may include vaporized liquids provided from a liquid evaporator located remotely from the gas box 142. A mixing apparatus may be disposed in the gas distribution assembly.

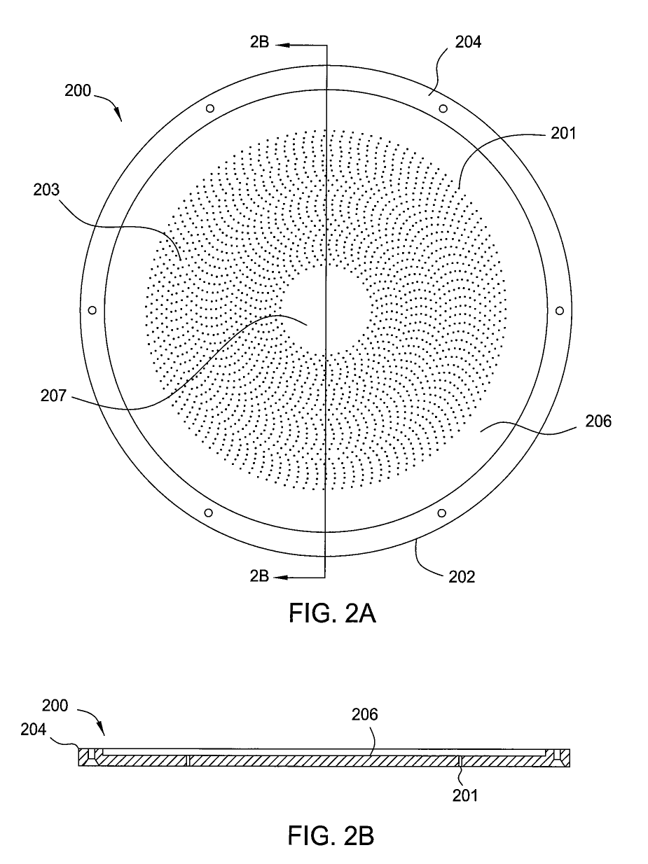

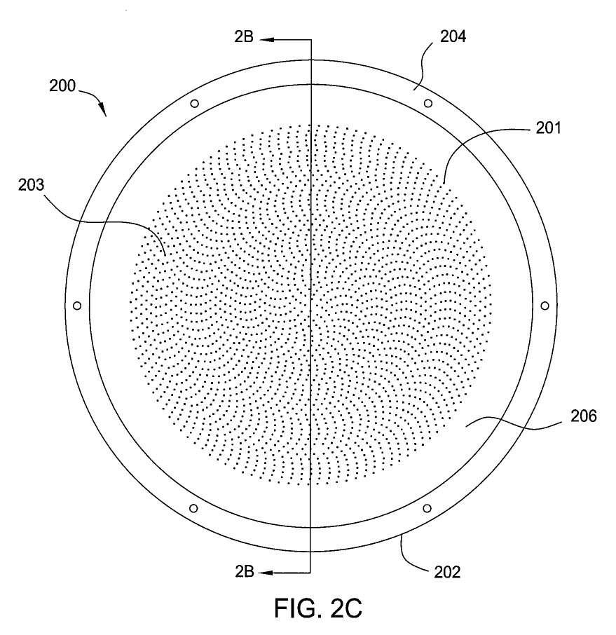

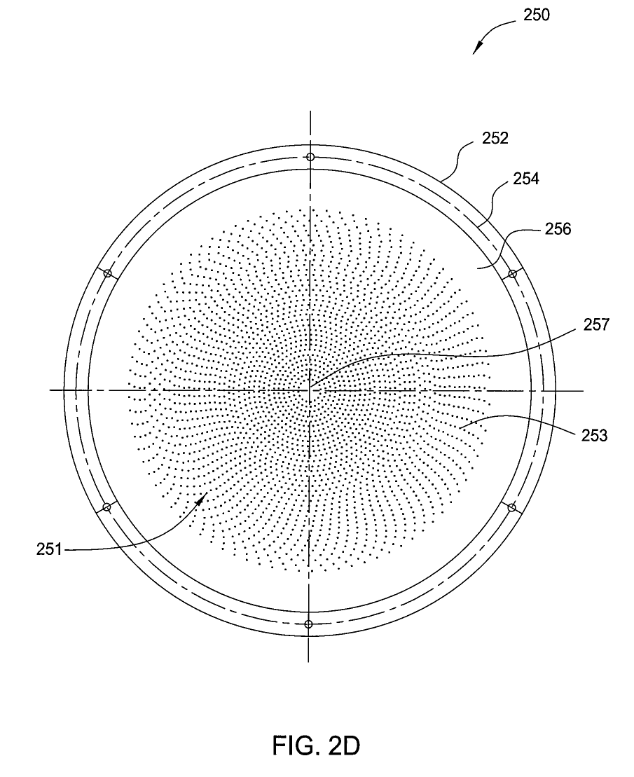

FIG. 2A is a schematic view of a blocker plate according to one embodiment described herein. FIG. 2B is a sectional view taken along line 2B of the blocker plate of FIG. 2A. The blocker plate 200 comprises an annular plate 202. The annular plate comprises an outer portion (annular lip) 204 surrounding an inner portion (a center portion) 206. A plurality of apertures 201 are formed through at least a portion of the inner portion and may be formed in a pattern as shown in FIG. 2A. The outer portion 204 may have an annular lip which is thicker or protrudes above a plane of the annular plate 202. In one embodiment of the annular plate, the annular plate has a thickness from 0.05 to 0.25 inches, such as about 0.15 inches. In one example, the annular lip has a thickness of about 0.1 inches greater than the inner portion of the annular plate 202. The annular lip may have a width of from 0.5 to 1 inch, such as about 0.87 inches. One or more bolt holes 214 may be formed through the raised concentric portion.

FIG. 2A illustrates a top schematic view of one embodiment of the blocker plate 200, the inner portion comprises a center portion (an inner portion) 207, a patterned portion 203, and a perimeter portion (outer portion) 206. The center portion and the perimeter portion may be a solid portion of the annular plate, for example, free of apertures.

The pattern portion 203 may comprise a plurality of apertures 201. The plurality of apertures may comprise an array of a plurality of radially spaced concentric circular rows of thirty or more apertures. The concentric circular rows may be spaced from each other from about 0.1 inches to about 0.5 inches, for example, about 0.25 inches from each other, and may further be equally spaced from one another. The apertures may be equally spaced from one another in each concentric circular row. Each aperture may have cylindrical shape in the annular plate. In one example, the apertures 201 may have a diameter from about 0.0125 inches to about 0.1 inches, such as about 0.025 inches, and extend through the annular plate to provide a passage for fluids therethrough. The patterned portion of the annular plate may vary based on the size of the annular plate, and can be at a diameter from about 2.3 to about 9.6 inches of the annular plate having a diameter of about 12.4 inches.

The plurality of concentric circular rows may be between about 10 and about 50 concentric circular rows, for example, 30 concentric circular rows. Each of the plurality of concentric circular rows may include between 30 and 150 apertures, such as between about 36 and about 123 apertures, with an angle of offset of the apertures of each concentric circular rows between 0° and 270°, such as between 63° and 260°, from a center line of the inner portion of the annular plate. The number of apertures and the offset angle may increase with each concentric circular row radiating from a center of the annular plate. For example, each row may increase from 2 to 4 apertures with an increasing offset angle from 5° to 10°, such as 7°. The plurality of apertures may comprise an aperture area density from about 25 apertures per square inch (apertures/in²) to about 50 apertures/in², for example, about 37.6 apertures/in². The apertures of the concentric circular rows may also be described as having an aperture circumference density (apertures/circumference inches) of between about 4 apertures/inch and about 5 apertures/inch. The aperture circumference density for the center and perimeter portions is zero (0).

In one example of the blocker plate, the patterned portion comprises 30 concentric circular rows, with the centermost concentric circular row comprising 36 apertures at an angle offset of about 63°, and the number of apertures for each concentric circular row increases between 2 to 4 apertures from the previous concentric circular row with an increasing offset angle of 7°, to the outer concentric circular row having 123 apertures with an angle of offset of about 266°. For example, the first 7 concentric circular rows from the centermost concentric circular row each increase by 4 apertures from the prior concentric circular row, the next 15 concentric circular rows each increase by 3 apertures from the prior concentric circular row, and the last 7 concentric circular rows from the centermost concentric circular row each increase by 2 apertures from the prior concentric circular row.

FIG. 2C illustrates a top schematic view of a second embodiment of the blocker plate 200, the inner portion comprises a pattern portion (an inner portion) 203 and a perimeter portion (outer portion) 206. The pattern portion may comprise a plurality of apertures 201. The plurality of apertures may comprise an array of a plurality of radially spaced concentric circular rows of two or more apertures. The apertures may be equally spaced from one another in each concentric circular row. The plurality of concentric circular rows may be between about 10 and about 50 concentric circular rows, for example, 30 concentric circular rows. Each of the plurality of concentric circular rows may include between 2 and 150 apertures, such as between about 4 and about 123 apertures, with an angle of offset of the apertures of each concentric circular rows between 0° and 270°, such as between 36° and 266°, from a center line of the inner portion of the annular plate. The number of apertures may increase with each concentric circular row radiating from a center of the annular plate. Each aperture may have cylindrical shape in the annular plate. In one example, the apertures 201 may have a diameter from about 0.0125 inches to about 0.1 inches, such as about 0.025 inches, and extend through the annular plate to provide a passage for fluids therethrough. The perimeter portion may be a solid portion of the annular plate, for example, free of apertures.

FIG. 2D illustrates a top schematic view of another embodiment of the blocker plate 250. The blocker plate 250 comprises an annular plate 252. The annular plate comprises an outer portion 254 surrounding an inner portion 256. The inner portion comprises a center portion 257, a patterned portion 253, and a perimeter portion 256. The center portion and the perimeter portion may be a solid portion of the annular plate, for example, free of apertures. The outer portion 254 may have an annular lip which is thicker or protrudes above a plane of the annular plate 252. In one embodiment of the annular plate, the annular plate has a thickness from 0.05 to 0.25 inches, such as about 0.15 inches. In one example, the annular lip has a thickness of about 0.1 inches greater than the inner portion of the annular plate 252. The annular lip may have a width of from 0.5 to 1 inch, such as about 0.87 inches. One or more bolt holes may be formed through the raised concentric portion.

The pattern portion 253 may comprise a plurality of apertures 251. The plurality of apertures may comprise an array of a plurality of radially spaced concentric circular rows of ten or more apertures. The concentric circular rows may be spaced from each other from about 0.1 inches to about 0.5 inches, for example, about 0.25 inches from each other, and may further be equally spaced from one another. The apertures may be equally spaced from one another in each concentric circular row. Each aperture may have cylindrical shape in the annular plate. In one example, the apertures 201 may have a diameter from about 0.0125 inches to about 0.1 inches, such as about 0.025 inches, and extend through the annular plate to provide a passage for fluids therethrough. The patterned portion of the annular plate may vary based on the size of the annular plate, and may have a width from a diameter of about 0.5 to about 9.1 inches of an annular plate having a diameter of about 12.4 inches.

The plurality of concentric circular rows may be between about 15 and about 50 concentric circular rows, for example, 35 concentric circular rows. Each of the plurality of concentric circular rows may include between 10 and 100 apertures, such as between about 16 and about 96 apertures, with an angle of offset of the apertures of each concentric circular rows between 0° and 270°, such as between 7° and 245°, from a center line of the inner portion of the annular plate. The number of apertures may vary with each concentric circular row radiating from a center of the annular plate. For example, each row may increase or decrease from 0 to 7 apertures. The number of apertures and the offset angle may increase with each concentric circular row radiating from a center of the annular plate. For example, each row may have an increasing offset angle from 5° to 10°, such as 7°.

The plurality of apertures may have a decreasing aperture area density as the concentric circular rows radiate from the center portion. The apertures of the concentric circular rows may also be described as having an aperture circumference density (apertures/circumference) of from about 10 apertures/inch to about 2 apertures/inch, such as from about 9.1 apertures/inch to about 2.9 apertures/inch. The aperture circumference density for the center and perimeter portions is zero (0). The aperture circumference density for each concentric circular row may decrease toward the perimeter of the pattern, such as a decrease from about 0.04 apertures/inch to about 0.38 apertures/inch between each of the concentric circular rows.

In one example of the blocker plate, the patterned portion comprises 35 concentric circular rows, with the centermost concentric circular row comprising 16 apertures at an angle offset of about 7°, and the number of apertures for each concentric circular row increasing or decreasing between 0 to 7 apertures from the previous concentric circular row with an increasing offset angle of 7°, to the outer concentric circular row having 85 apertures with an angle of offset of about 245°. For example, the first 7 concentric circular rows from the centermost concentric circular row each increase by 5 to 7 apertures from the prior concentric circular row, the next 13 concentric circular rows each increase by 1 to 4 apertures from the prior concentric circular row, the next 5 concentric circular rows each increase by 1 aperture or have the same number of apertures from the prior concentric circular row and the last 9 concentric circular rows from the centermost concentric circular row each decrease between 1 to 2 apertures or have the same number of apertures from the prior concentric circular row.

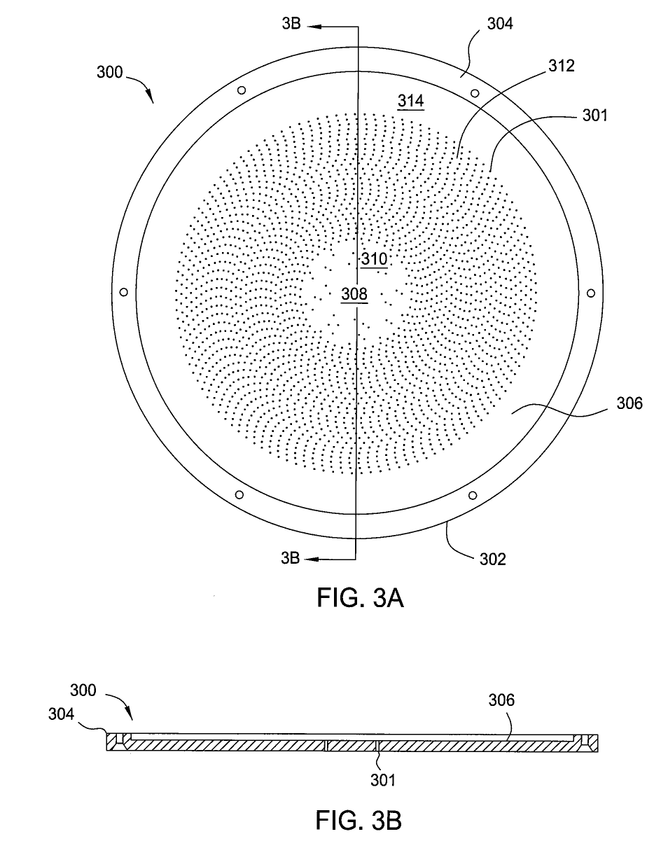

FIG. 3A is a schematic view of a second embodiment of a blocker plate as described herein. FIG. 3B is a sectional view taken along line 3B of the blocker plate of FIG. 3A. The blocker plate 300 comprises an annular plate 302. The annular plate comprises an outer portion (an annular lip portion) 304 and an inner portion 306 having a plurality of apertures 301 formed therethrough. The annular plate may have a diameter suitable for use in a gas distributor, such as from about 8 to about 16 inches, for example, about 12.4 inches in diameter.

The plurality of apertures 301 may form a first pattern as shown in FIG. 3A. The plurality of apertures 301 pattern in the annular plate may include a center portion 308, a first patterned portion (a middle portion) 310, a second patterned portion (an outer portion) 312, and a perimeter portion (a lip portion) 314 of the inner portion 306. The center portion 308 may be a solid portion of the annular plate, for example, free of apertures 301. The center portion 308 may comprise from about 5% to about 20% of the radius, such as 13%, of the inner portion 306.

The first patterned portion 310 includes first number or density of apertures 301 and may comprise from about 5% to about 20% of the radius, such as 13%, of the inner portion 306. The center portion 308 and the first patterned portion 310 may have the same radius length and may be formed in concentric circular rows. The first patterned portion of the annular plate may vary based on the size of the annular plate, and may have a width from a diameter of about 1.3 to about 2.6 inches of an annular plate having a diameter of about 12.4 inches.

In one embodiment of the first patterned portion 310, the first plurality of apertures 301 in the first patterned portion may comprise a first array of a plurality of radially spaced concentric circular rows of two or more apertures. The plurality of concentric circular rows may be between about 1 and about 10 concentric circular rows, for example, 6 concentric circular rows. The concentric circular rows may be spaced from each other from about 0.1 inches to about 0.5 inches, for example, about 0.25 inches from each other, and may further be equally spaced from one another. The apertures may be equally spaced from one another in each concentric circular row. Each concentric circular row of the plurality of concentric circular rows may include between 2 and 20 apertures, such as between about 4 and about 10 apertures, with an angle of offset of the apertures of each concentric circular row between 0° and 45° from a center line of the inner portion of the annular plate. The number of apertures may increase with each concentric circular row radiating from the center portion.

The first plurality of apertures may comprise a first aperture density. The density includes the aperture area density and/or the aperture circumference density as described herein. A first aperture area density may be from about 5 apertures per square inch (apertures/in²) to about 20 apertures/in², for example, about 11.6 apertures/in². The apertures of the concentric circular rows may also be described as having an aperture circumference density (apertures/circumference) of between about 0.9 apertures/inch and about 1.4 apertures/inch, such as between about 0.97 apertures/inch and about 1.27 apertures/inch. The aperture circumference density for the center and perimeter portions is zero (0) apertures/inch.

In one example of the blocker plate, the first patterned portion comprises 6 concentric circular rows, with the centermost concentric circular row comprising 4, and the number of apertures for each concentric circular row increases between 1 to 2 apertures from the previous concentric circular row to an outer concentric circular row of the first patterned portion having 10 apertures. The angles of offset for each row vary from 0° to about 30°.

The apertures 301 for the first patterned portion and the second patterned portion may have a diameter from about 0.0125 inches to about 0.1 inches, such as about 0.025 inches, and extend through the annular plate to provide a passage for fluids therethrough. Each aperture may have cylindrical shape in the annular plate.

The second patterned portion 312 includes a second number or density of the plurality of apertures 301 which is greater then the first density of apertures 301 for the first patterned portion 310. The density includes the aperture area density and/or the aperture circumference density as described herein. The second patterned portion 312 may comprise from about 35% to about 75% of the radius, such as 57%, of the inner portion 306. A perimeter portion 314 of the inner portion 306 may also be may be a solid portion of the annular plate, for example, free of apertures 301 and may comprise from about 15% to about 25% of the radius, such as 19%, of the inner portion 306. The second patterned portion of the annular plate may vary based on the size of the annular plate, and may have a width from a diameter of about 2.8 to about 9.1 inches of an annular plate having a diameter of about 12.4 inches.

In one embodiment of the blocker plate 300, the second plurality of apertures 301 in the second patterned portion may comprise a second array of a plurality of radially spaced concentric circular rows of two or more apertures. The plurality of concentric circular rows may be between about 10 and about 40 concentric circular rows, for example, 32 concentric circular rows. The concentric circular rows may be spaced from each other from about 0.1 inches to about 0.5 inches, for example, about 0.25 inches from each other, and may further be equally spaced from one another. The apertures may be equally spaced from one another in each concentric circular row. Each concentric circular row of the plurality of concentric circular rows may include between 15 and 125 apertures, such as between about 44 and about 119 apertures, with an angle of offset of the apertures of each concentric circular row between 0° and 252° from a center line of the inner portion of the annular plate. The number of apertures may increase with each concentric circular row radiating from the first patterned portion.

Thus, the second plurality of apertures may comprise a second aperture area density greater than the first aperture area density. The second aperture area density may be from greater than about 20 apertures per square inch (apertures/in²) (for example, about 25 apertures/in²) to about 50 apertures/in², for example, about 37.4 apertures/in². The apertures of the concentric circular rows may also be described as having an aperture circumference density (apertures/circumference) of between about 4 apertures/inch and about 5.5 apertures/inch, such as between about 4.18 apertures/inch and about 4.98 apertures/inch. The aperture circumference density for the center and perimeter portions is zero (0).

In one example of the blocker plate, the second patterned portion comprises 26 concentric circular rows, with the centermost concentric circular row comprising 44 apertures at an angle offset of about 77°, and the number of apertures for each concentric circular row increases between 2 to 4 apertures from the previous concentric circular row with an increasing offset angle of 7°, to the outer concentric circular row having 119 apertures with an angle of offset of about 252°. For example, the first 5 concentric circular rows from the centermost concentric circular row of the second patterned portion each increase by 4 apertures from the prior concentric circular row, the next 15 concentric circular rows each increase by 3 apertures from the prior concentric circular row, and the last 5 concentric circular rows from the centermost concentric circular row each increase by 2 apertures from the prior concentric circular row.

In another view, the second plurality of apertures may comprise a radial pattern of a plurality of rows and each row may comprise two or more sequential arc segments of two or more apertures. Further, each row may further comprise from 0 to 3 additional arc segments extending from the two or more sequential arc segments. The second plurality of aperture may comprise between 30 and 150 rows, such as about 44 rows.

The outer portion 304 may comprise a raised concentric portion disposed on a perimeter of the inner portion and having a thickness greater than the inner portion. In one embodiment of the annular plate, the annular plate has a thickness from 0.05 to 0.25 inches, such as about 0.15 inches. In one example, the raised concentric portion has a thickness about 0.1 inches greater than the inner portion. The outer portion may have a width of from 0.5 to 1 inch, such as about 0.87 inches. One or more bolt holes may be formed through the raised concentric portion 314.

It is believed that the design of the blocker plate 300 prevents flow of fluids in the center portion 308 and limits fluid flow in the first patterned portion 310. Such a design is believed to be critical to process utilizing water vapor because water vapor processes are temperature sensitive. As such the blocker plate 300 design minimizes the thermal effects of the heater when interacting with water vapor. Blocker plate 200 may be used in the above described chamber 100 for blocker plates 102. Blocker plate 300 may be used in the above described chamber 100 for blocker plates 102.

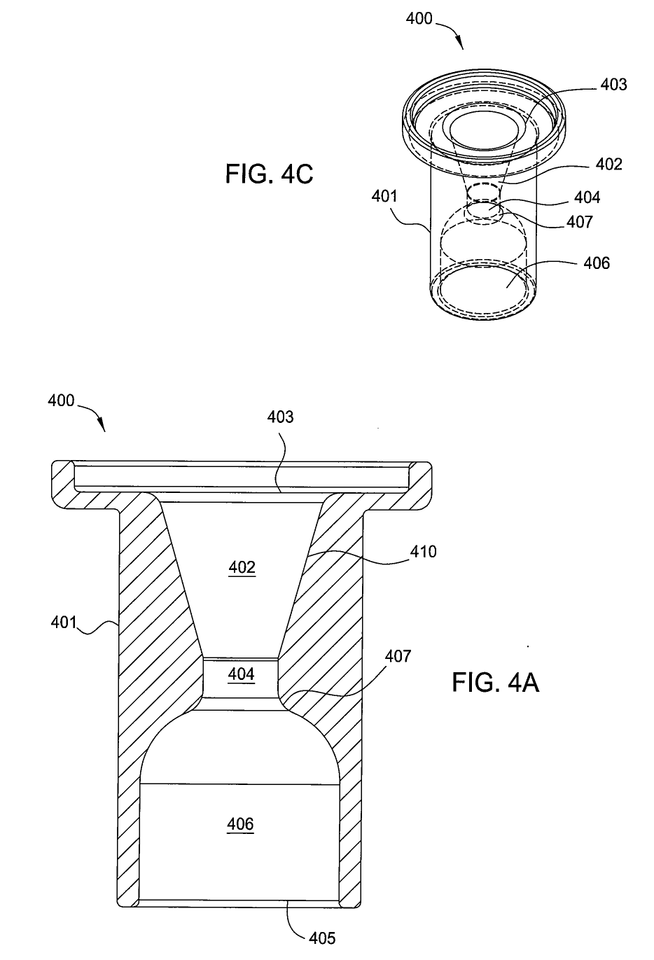

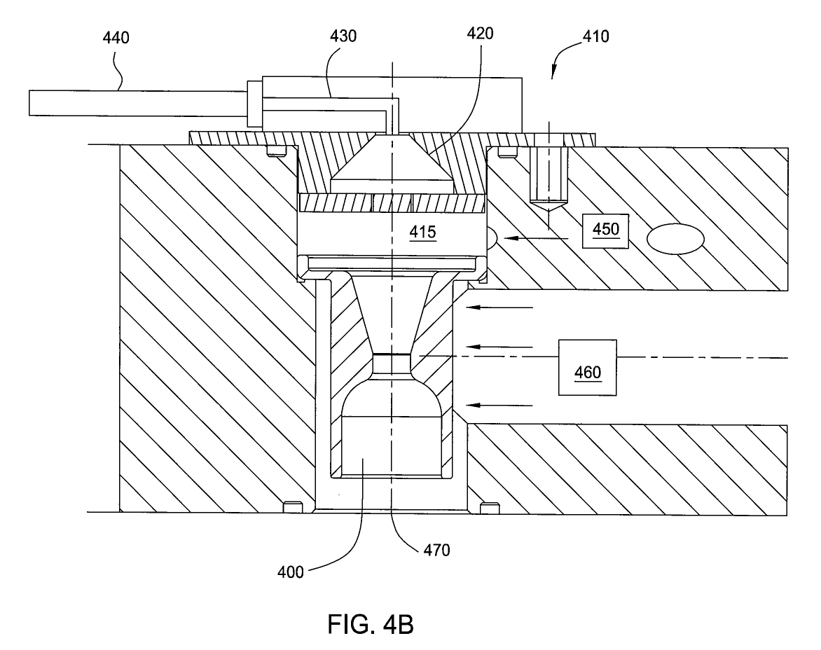

FIG. 4A is a cross-sectional view of a mixing apparatus 400, such as a funnel mixing tube, according to embodiments described herein. The mixing apparatus 400 may be disposed in a gas distribution assembly, such as gas distribution assembly 108 disclosed in FIG. 1.

The mixing apparatus 400 may have a substantially cylindrical body 401. In one embodiment of the mixing apparatus 400, the body has a cylindrical shape in the annular plate having an outer diameter between about 0.1 inches and about 8 inches, for example, 0.8 inches, and a height between about 0.1 inches and about 4 inches, such as about 1.7 inches to allow for more consistent installation and good concentricity a the mixing manifold.

In one embodiment of the mixing apparatus 400, the inner shape, or interior structure, of the mixing apparatus 400 has an hourglass shape with the minimum constraining inner diameter between about 0.1″ and about 1″ to allow repeatable and consistent gas mixing based on flow simulations and lab testing. However, the dimension of the portions of the mixing apparatus 400 may vary by use, design necessity, flow rate requirements, and other factors for optimum performance.

The interior structure 409 of the cylindrical body 401 comprises a series of fluid passage portions including a first portion 402 extending from an inlet 403 (or nozzle), a second portion 404 (a throat), and a third portion 406 (a diffuser) extending to an outlet 405. In one embodiment, The cylindrical body has cylindrical first, second, and third portions, with the second portion having a diameter less than the first portion, and a third portion having a diameter greater then the second portion and may have a diameter greater than or equal to the first portion. The inlet 403 and the outlet 405 may have diameters greater than the first portion 402, the second portion 404 and the third portion 406.

In one embodiment of the cylindrical body, the first portion 402 has a conical shape. The first portion 402 having a conical shape may taper from the inlet 403 to the second portion 404. In one embodiment of the cylindrical body, the third portion expands from the second portion to outlet 405.

In one embodiment of the mixing apparatus 400, an opening of the first portion is about 0.56 inches, the first portion 402 tapers to a second portion 404 having a diameter of about 0.24 inches, which then expends to a third portion 406 diameter near the outlet of about 0.64 inches. The second portion may further include a transition portion 407 to provide for a seamless transition from the second portion to the third portion. The transition portion 407 has a concave surface, for example, a concave surface with a radius of about 0.05 inches, which couples to the convex surface of the expanding portion of the third portion. The expanding portion may have a hemispherical profile, such as a concave profile. The hemispherical profile may exhibit a radius of curvature, for example, about 0.318 inches, from a center line of the third portion. Alternatively, the expanding portion may have a conical shape.

The height of the first, second, and third portion may vary according to the needs of the chamber, and in one example, the first portion has a height of about 0.63 inches, a second portion has a height of about 0.3 inches, and a third portion having a height of about 0.75 inches.

It is believed that a funnel mixing design to contract the rotating gases is easier to manufacture than the prior funnel mixing tube. The funnel mixing design can decrease process variance due to mixing hardware manufacturing and installation tolerance, reduced yield left and right mismatch (yield reduced L/R mismatch) due to conductance variance in the complex angled hole design of the prior chamber inserts.

The funnel mixing tube design may be modified to obtain desired mixing properties. A lip design may be used to improve installation concentricity. The radius for exit region may be used to improve the flow regime. The respective dimension of the funnel mixing tube may be changed for the dimension layout of shape for height of cylinder, diameter of cylinder, angle of entry, and exit regime. The change in dimensions on top of part may be used to aid instability and concentricity of the installed part.

FIG. 4B is a cross-sectional view of one embodiment of a funnel mixing tube disposed in a gas distribution assembly. The gas distribution assembly 410 may be gas distribution assembly 108 disclosed in FIG. 1. The mixing apparatus 400 may be disposed in the gas distribution assembly 410 and coupled to a gas entry region 415 by the inlet 403 and the cylindrical body first portion 402. The gas entry region may be fluidly coupled to a source of processing gases through conduit 450, such as a mixture of tetraethoxyl silane (TEOS) and oxygen or ozone gas and a vaporized liquid line 430 such as from a liquid evaporator 500 shown below. The vaporized liquid line may be encapsulated by a heated water line 440 to provide the vaporized liquid at a temperature to minimize condensation in the respective line. The vaporized liquid line may pass through an expansion conduit 420 before the gas entry region 415. The gases and the vaporized liquid can then be delivered to a processing region of a processing chamber 480.

The third portion of the mixing apparatus 400 is in fluid communication with a processing region 470 of a processing chamber. A plasma gas, such as from a remote plasma source including cleaning gases may be flowed into the processing region 470 of the chamber around the mixing apparatus 400 by conduit 460.

FIG. 4C is an isometric cross-sectional view of one embodiment of the funnel mixing tube of FIG. 4A, and shows the first portion 402, the second portion 404, and the third portion 406.

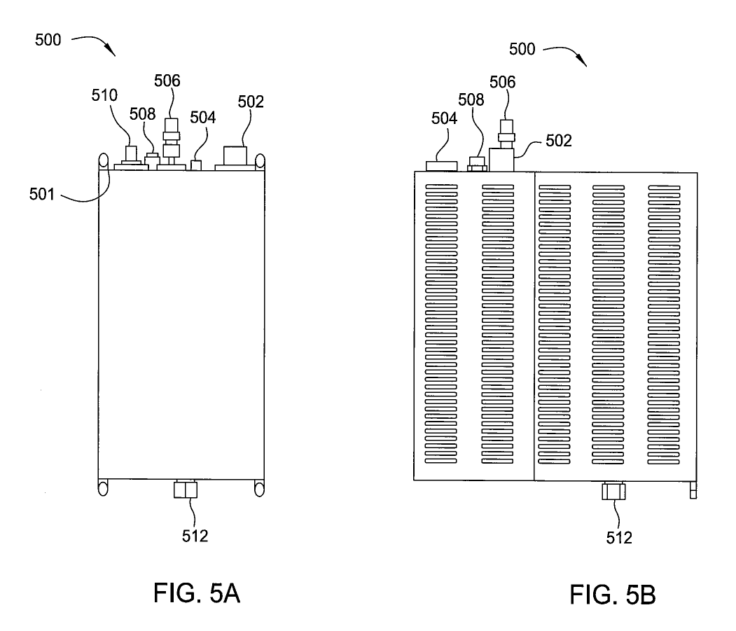

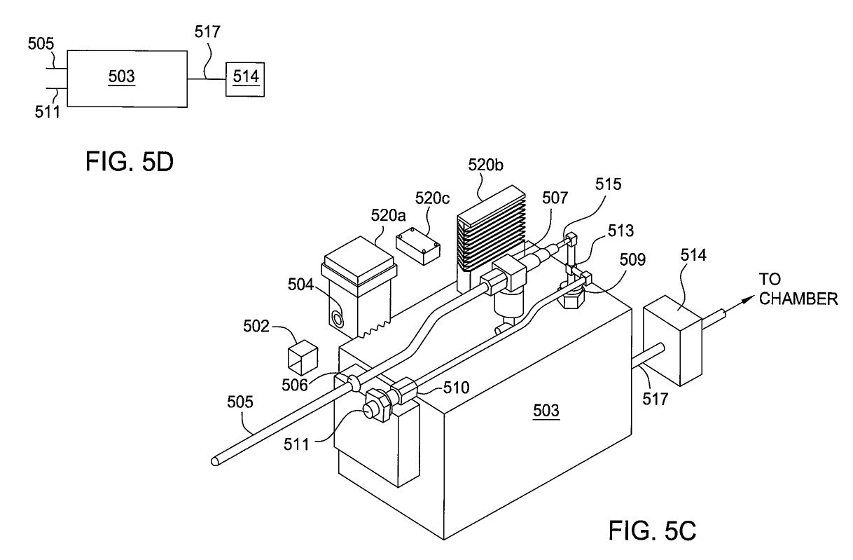

FIGS. 5A and 5B are schematic top and side views of a liquid evaporator according to one embodiment described herein. The liquid evaporator 500 includes a series of ports on one side 501. The vaporized liquid may then be delivered to the chamber via the outlet 512. The ports include a power inlet 502, a signal connector 504, a first fluid line inlet 506, such as a water inlet, a third fluid inlet 508, such as an air inlet, and a second fluid inlet 510, such as a nitrogen gas inlet. The vaporized liquid may then be delivered to the chamber via the outlet 512. The liquid evaporator 500 can be used to evaporate a liquid used in a deposition or treatment process, such as water.

The liquid evaporator may be run at an operating water pressure from 0.2 to 0.3 MPa, a carrier gas pressure of 0.2 to 0.3 MPa, a carrier gas maximum flow rate of 20 SLM, and operating air pressure pneumatic value from 0.4 to 0.6 MPa, and an operating ambient temperature range from 15° C. to 35° C. The temperature setting for operating the vaporizer may be 110° C.

FIG. 5C is a perspective view of one embodiment of a vaporizer disposed in the liquid evaporator 500. A first fluid line 505, such as water line from a water source, is disposed through the first fluid line inlet, water inlet, 506 and is coupled to a shutoff valve 507. The shutoff valve 507 is shown disposed on a top portion of the vaporizer 503, and may alternatively, be disposed in any other arrangement with the vaporizer as necessary. The shutoff valve 507 is coupled to the vaporizer 503 via the mixed fluid line 509.

A second fluid line 511, such as a nitrogen gas line from a nitrogen source, is disposed through second fluid inlet, nitrogen gas inlet, 510 and is coupled to the mixed fluid line 509 via the line junction 513 to mix with water prior to entry into the vaporizer 503. The line portion 515 disposed between the shutoff valve 507 and the line junction 513 is of minimized length, such as from 1 inch to 2 inches, to minimize the water volume upstream of the line junction 513 and the vaporizer 503. However, the length of line portion 515 may vary based on the design and/or size of the vaporizer, the volume of liquid flow through the lines, and the placement of the flow lines utilized. Reducing the length of water line portion 515 is believed to prevent unwanted water evaporation. Water evaporation produces processing instability in the vaporizer, which instability increases the time to establish steady state flows and process variations.

A vaporizer shutoff valve 514 may be disposed downstream of the vaporizer 503 on outlet line 517 passing through vaporizer outlet 512. The vaporizer shutoff valve restricts or prevents vaporized water flow to the processing chamber. The shutoff valve 514 is preferably disposed as close to the vaporizer as possible, such as from 0.1 inches to 1 inches, to minimize the vaporized water flow volume downstream of the vaporizer 503 when the shutoff valve 514 is in a closed position. In one embodiment of the vaporizer, the vaporizer shutoff valve is coupled directly to the outlet 512. However, the distance may vary based on the design and/or size of the vaporizer and vaporizer shutoff valve.

FIG. 5D is a schematic side view of one embodiment of the vaporizer 503 having a first fluid line 505 of a water line and a second fluid line 511 of a nitrogen line providing fluids to the vaporizer 503, an outlet line 517 to provide vaporized liquids to the chamber, and a vaporizer shutoff valve 514 to control flow in the outlet line 517 to a processing chamber.

A thermal regulation apparatus 520a-520c is also coupled to the vaporizer to control the temperature of the vaporization process. A thermal controller 520a is coupled to the chamber to monitor and modify the temperature of the vaporization process. A heat exchanger device 520b of the thermal regulation apparatus is coupled to the vaporizer allowing for dissipation of heat from the vaporizer. The thermal controller is coupled to an external system through a signal connector 504. The vaporizer is coupled to a power source through the power inlet 502.

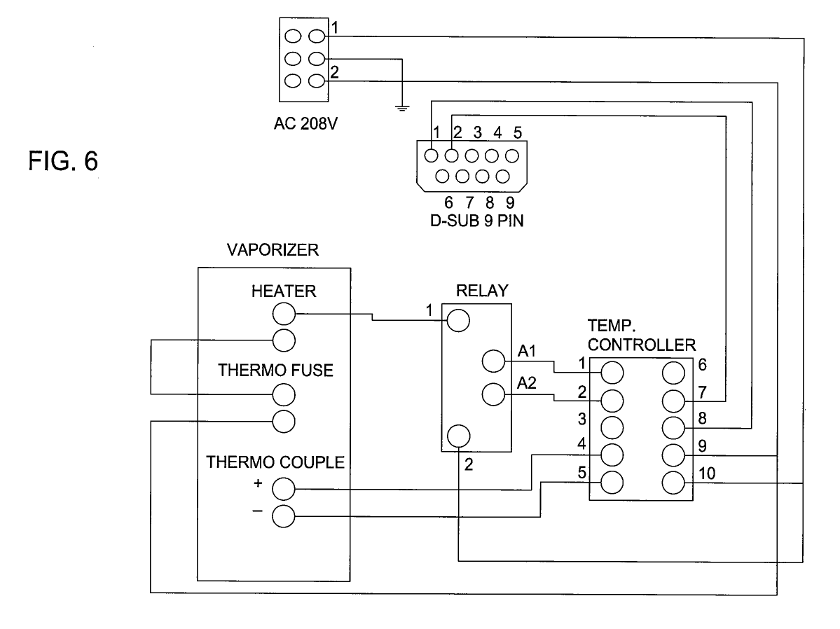

FIG. 6 is a schematic diagram for the electronic system of the liquid evaporator according to one embodiment described herein.

While the foregoing is directed to embodiments of the present invention, other and further embodiments of the invention may be devised without departing from the basic scope thereof, and the scope thereof is determined by the claims that follow.

What is claimed is:

1. A blocker plate, comprising:
an annular plate having an inner portion of a first thickness and the annular plate having an aperture pattern comprising:
a center portion;
a first patterned portion concentrically disposed around the center portion and comprising a first plurality of apertures having a first number of apertures;
an second patterned portion concentrically disposed around the first patterned portion and comprising a second plurality of apertures having a second number of apertures greater than the first number of apertures;
a perimeter portion concentrically disposed around the second patterned portion; and
an outer portion comprising a raised concentric portion disposed on a perimeter of the annular plate and having a second thickness greater than the first thickness of the center portion.

2. The blocker plate of claim 1, wherein the first plurality of apertures comprises a first plurality of concentric circular rows of two or more apertures the second plurality of apertures comprises a second plurality of concentric circular rows of two or more apertures.

3. The blocker plate of claim 2, wherein the first plurality of concentric circular rows comprises from 2 to about 10 concentric circular rows each having from 2 to 20 apertures with an angle of offset of the apertures of each ring from about 0 to about 45° from a center line of the inner portion of the annular plate.

4. The blocker plate of claim 2, wherein the second plurality of concentric circular rows comprises from 10 to 40 concentric circular rows each having from 44 to 119 apertures with an angle of offset of the apertures of each ring from about 77° to about 252° from a center line of the inner portion of the annular plate.

5. The blocker plate of claim 1, wherein each aperture of the first plurality of apertures and the second plurality of aperture are cylindrical in shape.

6. A blocker plate, comprising:
an annular plate having an inner portion of a first thickness and the annular plate having an aperture pattern comprising:
a center portion;
a patterned portion concentrically disposed around the center portion and comprising a plurality of apertures, wherein the plurality of apertures comprises a plurality of concentric circular rows each having an increasing number between 30 and 150 apertures with each ring having an angle of offset between 60° and 270° for a center line of the center portion;
a perimeter portion concentrically disposed around the center portion; and
an outer portion comprising a raised concentric portion disposed on a perimeter of the annular plate and having a second thickness greater than the first thickness of the inner portion.

7. The blocker plate of claim 6, wherein the center portion and the perimeter portion are free of apertures and each aperture of the plurality of apertures are cylindrical in shape.

8. A mixing apparatus, comprising:
a body defining an interior structure adapted to process a fluid, the interior structure comprising:
a first portion extending from an inlet;
a cylindrical second portion coupled to the first portion; and
a third portion coupled to the second portion and extending to an outlet with the third portion comprising an expanding portion coupled to the second portion and a cylindrical portion coupled to the expanding portion and the outlet and the first portion has a conical shape and tapers from the inlet to the second portion.

9. The mixing apparatus of claim 8, wherein the mixing apparatus is disposed in a gas distribution assembly and coupled to a gas entry region by the inlet and the outlet is in fluid communication with a processing volume of a processing chamber.

10. The mixing apparatus of claim 8, wherein the expanding portion comprises a hemispherical profile extended from the second portion to the cylindrical portion of the third portion.

11. The mixing apparatus of claim 8, wherein the second portion having a diameter less than the first portion, and a third portion having a cylindrical portion diameter greater than the second portion.

12. The mixing apparatus of claim 8, wherein the third portion has a cylindrical portion diameter greater than or equal to the first portion.

13. A liquid evaporating apparatus, comprising:
a vaporizer;
a mixed fluid line coupled to the vaporizer;
a first fluid shutoff valve disposed on a top portion of the vaporizer and coupled to the mixed fluid line;
a first fluid line coupled to the mixed fluid line by the first fluid shutoff valve;
a second fluid line coupled to the mixed fluid line; and
a vaporizer shutoff valve disposed in fluid communication with the vaporizer.

14. The liquid evaporating apparatus of claim 13, wherein the first fluid line is a water line and the second fluid line is a nitrogen gas line.

15. The liquid evaporating apparatus of claim 13, wherein the mixed fluid line, the first fluid line and the second fluid are coupled together at a line junction disposed upstream of the vaporizer.

16. The liquid evaporating apparatus of claim 13, wherein the first fluid shutoff valve is disposed from 1 inch to 2 inches from the line junction and the vaporizer shutoff valve is disposed downstream of the vaporizer from about 0.1 inches to about 1 inches from the vaporizer.

17. The liquid evaporating apparatus of claim 13, wherein the vaporizer shutoff valve is directly coupled to the vaporizer.

18. The liquid evaporating apparatus of claim 13, further comprising a thermal controller and heat exchanger device coupled to the vaporizer.

19. A blocker plate, comprising:
an annular plate having an inner portion of a first thickness and the annular plate having an aperture pattern comprising:
a center portion;
a patterned portion concentrically disposed around the center portion and comprising a plurality of apertures, wherein the plurality of apertures comprises a plurality of concentric circular rows each having a varying number of apertures between 16 and 96 apertures with each ring having an angle of offset between 7° and 245° from a center line of the center portion;
a perimeter portion concentrically disposed around the center portion; and
an outer portion comprising a raised concentric portion disposed on a perimeter of the annular plate and having a second thickness greater than the first thickness of the inner portion.

20. The blocker plate of claim 19, wherein the center portion and the perimeter portion are free of apertures and wherein each aperture of the plurality of apertures are cylindrical in shape.
